(19) United States
(12) Patent Application Publication
(10) Pub. No.: US 2025/0290747 A1
(43) Pub. Date: Sep. 18, 2025

(54) OPTICAL ARRANGEMENT FOR A METROLOGY SYSTEM

(71) Applicant: ASML Netherlands B.V., Veldhoven (NL)

(72) Inventors: Kuang-Yu Yang, Taipei (TW); Roxana Rezvani Naraghi, Easton, CT (US); Changsik Yoon, Waalre (NL)

(21) Appl. No.: 18/860,248

(22) PCT Filed: Apr. 18, 2023
(86) PCT No.: PCT/EP2023/060047

§ 371 Date: Oct. 25, 2024

Related U.S. Application Data
(60) Provisional application No. 63/341,220, filed on May 12, 2022.

(51) Int. Cl. G01B 11/27; G02B 27/14; G03F 7/00

(52) U.S. Cl. CPC G01B 11/272; G02B 27/149; G03F 7/70633; G03F 7/706845; G03F 7/706849

(57) ABSTRACT

An optical arrangement eliminates the use of a quad non polarized beam splitter (QNPBS) and the need for image stitching. The optical arrangement provides an enhanced transmission gain as with a QNPBS to optimize system throughput. A metrology system (600) includes an illumination mode selector (IMS) (650) comprising a multi-aperture pattern having transmissive portions and reflective portions. The IMS (650) is positioned in a pupil plane (655) of the system (600), and configured to: transmit portions (671) of radiation (604) toward a diffraction grating target (610); and reflect diffracted radiation from the target (610) along a second optical path (631) toward a detector (662). Area decoupling of transmissive and reflective portions on the IMS (650) optimizes the illumination and detection light intensity simultaneously. Plus and minus first diffraction order diffracted radiation from the target (610) may be reflected by two reflective quadrants of the multi-aperture pattern, the two reflective quadrants located on a back or non-radiation source facing side (651) of the IMS (650).

### CROSS-REFERENCE TO RELATED APPLICATIONS

This application claims priority of U.S. application 63/341,220 which was filed on May 12, 2022 and which is incorporated herein in its entirety by reference

### TECHNICAL FIELD

This description relates to an optical arrangement for a metrology system.

### BACKGROUND

A lithographic projection apparatus can be used, for example, in the manufacture of integrated circuits (ICs). A patterning device (e.g., a mask) may include or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate includes a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices as described herein can be gleaned, for example, from U.S. Pat. No. 6,046,792, incorporated herein by reference.

Prior to transferring the pattern from the patterning device to the substrate, the substrate may undergo various procedures, such as priming, resist coating, and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, deposition, chemo-mechanical polishing, etc., all intended to finish the individual layer of the device. If several layers are required in the device, then the whole procedure, or a variant thereof, is repeated for each layer. Eventually, a device will be present in each target portion on the substrate. These devices are then separated from one another by a technique such as dicing or sawing, such that the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, deposition, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, deposition, etc.

Lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but are not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET).

### SUMMARY

A metrology system optical arrangement eliminates the use of a quad non polarized beam splitter and therefore the need for image stitching. The optical arrangement provides an enhanced transmission gain as with a quad non polarized beam splitter to optimize system throughput. The system includes an illumination mode selector comprising a multi-aperture pattern having transmissive portions and reflective portions. The illumination mode selector is positioned in a pupil plane of the system, and configured to: transmit portions of radiation toward a diffraction grating target; and reflect diffracted radiation from the diffraction grating target along a second optical path toward a detector. The area decoupling of transmissive and reflective portions on the illumination mode selector is favorable to optimize the illumination and detection light intensity simultaneously. About 50% of the radiation is transmitted through two transmissive quadrants of the multi-aperture pattern. Plus and minus first diffraction order diffracted radiation from the diffraction grating target is reflected by two reflective quadrants of the at least on multi-aperture pattern, the two reflective quadrants located on a back or non-radiation source facing side of the optical element.

According to an embodiment, a metrology system is provided. The system comprises an optical element comprising at least one multi-aperture pattern with transmissive and reflective portions. The optical element is positioned in a pupil plane of the system. The optical element is configured to receive radiation from a radiation source along a first optical path, and transmit portions of the radiation through the transmissive portions of the at least one multi-aperture pattern toward a diffraction grating target. The optical element is configured to reflect, with the reflective portions of the at least one multi-aperture pattern, diffracted radiation from the diffraction grating target along a second optical path toward a detector.

In some embodiments, about 50% of the radiation is transmitted through two transmissive quadrants of the at least one multi-aperture pattern. The two transmissive quadrants form the transmissive portions of the at least one multi-aperture pattern.

In some embodiments, plus and minus first diffraction order diffracted radiation from the diffraction grating target is reflected by two reflective quadrants of the at least on multi-aperture pattern. The two reflective quadrants are located on a back or non-radiation source facing side of the optical element. The two reflective quadrants form the reflective portions of the at least one multi-aperture pattern.

In some embodiments, the optical element is an illumination mode selector. In some embodiments, the illumination mode selector is movable to facilitate selection of the at least one multi-aperture pattern from among other different possible multi-aperture patterns. In some embodiments, the illumination mode selector is a rotatable wheel with the at least one multi-aperture pattern and the other different possible multi-aperture patterns formed therein.

In some embodiments, the at least one multi-aperture pattern comprises four quadrants, with first and third opposing quadrants comprising two opposing apertures forming the transmissive portions, and second and fourth opposing quadrants comprising the reflective portions of the at least one multi-aperture pattern.

In some embodiments, the two opposing apertures are configured to split the radiation into a first sub-beam and a second sub-beam, direct the first sub-beam through a first optical branch of the system to form a first spot, and direct the second sub-beam through a second optical branch of the system to form a second spot.

In some embodiments, the reflective portions are configured to reflect diffracted plus and minus first order radiation through a detector branch of the system along the second optical path to the detector. The detector is configured to receive the diffracted first order radiation and generate a detection signal.

In some embodiments, the system comprises an alignment branch beam splitter configured to transmit transmitted radiation from the transmissive portions of the at least one multi-aperture pattern. The alignment branch beam splitter is not in a common path with the detector branch. In some embodiments, the alignment branch beam splitter is a transmissive optic cube. In some embodiments, the alignment branch beam splitter is positioned between the optical element and the diffraction grating target, and the optical element is not coupled to an alignment branch of the metrology system.

In some embodiments, the at least one multi-aperture pattern comprises two opposing apertures that form the transmissive portions, each opposing aperture comprising an orifice shaped as a sector of a circle.

In some embodiments, the optical element is configured to replace a quad non polarizing beam splitter in the metrology system.

In some embodiments, the reflective portions are formed by coating a reflective coating on select portions of an optical element body.

In some embodiments, the system comprises the radiation source. The radiation source is configured to generate the radiation along the first optical path.

In some embodiments, the system comprises the detector. The detector is configured to receive diffracted and reflected first order radiation from first and second illumination spots on diffraction grating targets and generate a detection signal.

In some embodiments, the optical element forms a portion of an alignment sensor and/or an overlay detection sensor.

In some embodiments, the alignment sensor and/or the overlay detection sensor is configured for a semiconductor wafer, and is used in a semiconductor manufacturing process.

According to another embodiment, another metrology system is provided. The metrology system comprises a first optical element formed by a rotatable disk comprising at least one multi-aperture pattern. The first optical element is positioned in a pupil plane of the system. The first optical element is configured to receive radiation from a radiation source, and transmit portions of the radiation through transmissive portions of the at least one multi-aperture pattern and a relay lens pair toward a diffraction grating target. The metrology system comprises a second optical element comprising a quad beam splitter with transmissive portions and reflective portions. The transmissive portions of the quad beam splitter are configured to transmit a first portion of radiation received from the first optical element along a first optical path, and a second portion of the radiation along a second optical path, toward the diffraction grating target, and focus corresponding spots of radiation on the diffraction grating target. The reflective portions of the quad beam splitter are configured to reflect diffracted radiation from the diffraction grating target along a third optical path toward a detector.

According to another embodiment, a metrology method is provided. The metrology method comprises receiving radiation from a radiation source along a first optical path, and transmitting portions of the radiation through transmissive portions of at least one multi-aperture pattern toward a diffraction grating target, the at least one multi-aperture pattern formed in an optical element, the at least one multi-aperture pattern comprising the transmissive portions and reflective portions, the optical element positioned in a pupil plane of a metrology system; and reflecting, with the reflective portions of the at least one multi-aperture pattern, diffracted radiation from the diffraction grating target along a second optical path toward a detector.

According to another embodiment, there is provided another metrology method, comprising: receiving radiation from a radiation source with a first optical element formed by a rotatable disk comprising at least one multi-aperture pattern, the first optical element positioned in a pupil plane of the system, and transmitting portions of the radiation through transmissive portions of the at least one multi-aperture pattern and a relay lens pair toward a diffraction grating target; and transmitting, with a second optical element comprising a quad beam splitter with transmissive portions and reflective portions, a first portion of radiation received from the first optical element along a first optical path, and a second portion of the radiation along a second optical path, toward the diffraction grating target, and focus corresponding spots of radiation on the diffraction grating target, the reflective portions of the quad beam splitter configured to reflect diffracted radiation from the diffraction grating target along a third optical path toward a detector. In some embodiments, this may extend to dual objective sensors and a detection branch.

According to another embodiment, a system for generating spots of radiation configured to be directed at a diffraction grating target for an overlay detection sensor used in a semiconductor manufacturing process is provided. The system is configured to generate multiple spots of radiation. The system is configured to eliminate a need for a quad non polarizing beam splitter and therefore a need for alignment image stitching. The system comprises a radiation source. The system comprises an illumination mode selector comprising at least one multi-aperture pattern having transmissive portions and reflective portions. The illumination mode selector is positioned in a pupil plane of the system. The illumination mode selector is configured to: receive radiation from the radiation source along a first optical path, and transmit portions of the radiation through the transmissive portions of the at least one multi-aperture pattern toward the diffraction grating target; and reflect, with the reflective portions of the at least one multi-aperture pattern, diffracted radiation from the diffraction grating target along a second optical path toward a detector. About 50% of the radiation is transmitted through two transmissive quadrants of the at least one multi-aperture pattern. The two transmissive quadrants forming the transmissive portions of the at least one multi-aperture pattern. Plus and minus first diffraction order diffracted radiation from the diffraction grating target is reflected by two reflective quadrants of the at least on multi-aperture pattern. The two reflective quadrants are located on a back or non-radiation source facing side of the optical element. The two reflective quadrants form the reflective portions of the at least one multi-aperture pattern. The system comprises the detection sensor. The detection sensor is configured to receive diffracted and reflected plus and minus first order radiation from the diffraction grating target and generate an overlay detection signal based on the diffracted and reflected plus and minus first order radiation.

### BRIEF DESCRIPTION OF THE DRAWINGS

The above aspects and other aspects and features will become apparent to those ordinarily skilled in the art upon review of the following description of specific embodiments in conjunction with the accompanying figures.

FIG. 1 schematically depicts a lithography apparatus, according to an embodiment.

FIG. 2 schematically depicts an embodiment of a lithographic cell or cluster, according to an embodiment.

FIG. 3 schematically depicts an example inspection system, according to an embodiment.

FIG. 4 schematically depicts an example metrology technique, according to an embodiment.

FIG. 5 illustrates the relationship between a radiation illumination spot of an inspection system and a metrology target, according to an embodiment.

FIG. 6 illustrates a system configured for generating one or more spots of illumination configured to be directed at one or more metrology targets such as one or more diffraction grating targets, according to an embodiment.

FIG. 7 illustrates an optical element comprising an illumination mode selector of the present system, according to an embodiment.

FIG. 8 illustrates a multi-aperture pattern comprising four quadrants, two transmissive and two reflective, according to an embodiment.

FIG. 9 illustrates an alternative form of the present system, according to an embodiment.

FIG. 10 illustrates a metrology method, according to an embodiment.

FIG. 11 is a block diagram of an example computer system, according to an embodiment.

### DETAILED DESCRIPTION

In semiconductor device manufacturing, metrology operations typically include determining the position of a metrology mark (or marks) and/or other target in a layer of a semiconductor device structure. This position is typically determined by irradiating a metrology mark with radiation, and comparing characteristics of different diffraction orders of radiation reflected from the metrology mark. Such techniques are used to measure overlay, alignment, and/or other parameters.

Prior metrology systems use a quad non-polarizing beam splitter (NPBS) to transmit radiation to a target such as a metrology mark, and reflect diffracted radiation from the metrology mark to a detector. However, this design includes a constraint that it does not provide a full field of view, and therefore requires image stitching. Image stitching introduces (e.g., alignment) error, which is not desired, and negatively impacts the ability of these prior metrology systems to meet future specifications.

Advantageously, the present system(s) and method(s) provide a new optical design architecture for a metrology system that eliminates the use of a quad non-polarizing beam splitter and therefore the need for (e.g., alignment) image stitching. Instead of a quad non-polarizing beam splitter, shaped apertures and corresponding reflective portions are provided on an illumination mode selector (wheel for example), which is positioned in the pupil plane of the metrology system. This combines the functionality of illumination mode selector aperture patterning and a quad non-polarizing beam splitter, using a high reflection coating on the portions of an illumination mode selector, at the pupil plane. This way, diffracted first order radiation can be reflected to a detector branch of the system. Since the illumination mode selector with the shaped apertures and reflective portions is conjugated to the pupil plane and is not in a common path with an alignment branch of the metrology system, the present metrology system does not suffer from the image stitching and error issues observed in prior metrology systems. Moreover, to meet future requirements, for example, reflected radiation from the illumination mode selector can be directed to a second objective and enable a low-cost high photon efficient dual objective sensor. Thanks to the functionality of the illumination mode selector, the diffracted first orders from two objective sensors can be synchronously measured with a single detection branch by transmitted/reflected diffracted first order radiation from the reflected/transmitted radiation, respectively.

By way of a brief introduction, the description below relates to semiconductor device manufacturing and patterning processes. The following paragraphs also describe several components of systems and/or methods for semiconductor device metrology. These systems and methods may be used for measuring overlay, alignment, etc., in a semiconductor device manufacturing process, for example, or for other operations.

Although specific reference may be made in this text to the measurement of overlay, alignment, or other parameters, and the manufacture of integrated circuits (ICs) for semiconductor devices, it should be understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle,” “wafer” or “die” in this text should be considered as interchangeable with the more general terms “mask,” “substrate” and “target portion,” respectively.

The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

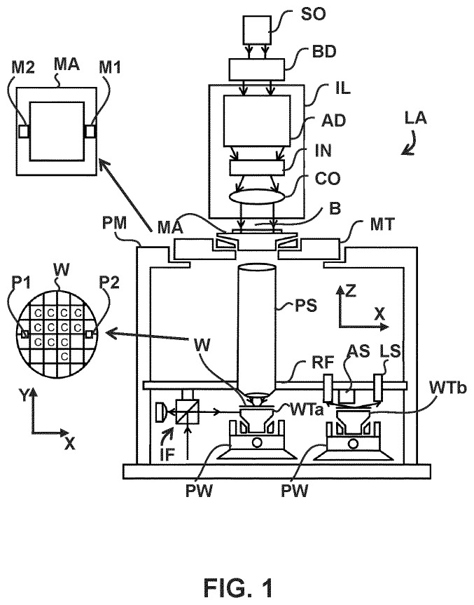

FIG. 1 schematically depicts an embodiment of a lithographic apparatus LA. The apparatus comprises an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame RF. As depicted, the apparatus is of a transmissive type (e.g. employing a transmissive mask). Alternatively, the apparatus may be of a reflective type (e.g. employing a programmable mirror array, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system. Any use of the terms “reticle” or “mask” herein may be considered synonymous with the more general term “patterning device.”

The term “patterning device” used herein should be broadly interpreted as referring to any device that can be used to impart a pattern in a target portion of the substrate. In an embodiment, a patterning device is any device that can be used to impart a radiation beam with a pattern in its cross-section to create a pattern in a target portion of the substrate. It should be noted that the pattern imparted to the radiation beam may not exactly correspond to the desired pattern in the target portion of the substrate, for example if the pattern includes phase-shifting features or so called assist features. Generally, the pattern imparted to the radiation beam will correspond to a particular functional layer in a device being created in a target portion of the device, such as an integrated circuit.

A patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted to reflect an incoming radiation beam in different directions. The tilted mirrors impart a pattern in a radiation beam, which is reflected by the mirror matrix.

The term “projection system” should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system.”

The projection system PS may comprise a plurality of optical (e.g., lens) elements and may further comprise an adjustment mechanism configured to adjust one or more of the optical elements to correct for aberrations (phase variations across the pupil plane throughout the field). To achieve this, the adjustment mechanism may be operable to manipulate one or more optical (e.g., lens) elements within the projection system PS in one or more different ways. The projection system may have a co-ordinate system wherein its optical axis extends in the z direction. The adjustment mechanism may be operable to do any combination of the following: displace one or more optical elements; tilt one or more optical elements; and/or deform one or more optical elements. Displacement of an optical element may be in any direction (x, y, z, or a combination thereof). Tilting of an optical element is typically out of a plane perpendicular to the optical axis, by rotating about an axis in the x and/or y directions although a rotation about the z axis may be used for a non-rotationally symmetric aspherical optical element. Deformation of an optical element may include a low frequency shape (e.g. astigmatic) and/or a high frequency shape (e.g. free form aspheres). Deformation of an optical element may be performed for example by using one or more actuators to exert force on one or more sides of the optical element and/or by using one or more heating elements to heat one or more selected regions of the optical element. In general, it may not be possible to adjust the projection system PS to correct for apodization (transmission variation across the pupil plane). The transmission map of a projection system PS may be used when designing a patterning device (e.g., mask) MA for the lithography apparatus LA. Using a computational lithography technique, the patterning device MA may be designed to at least partially correct for apodization.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be conducted on one or more tables while one or more other tables are being used for exposure. For example, alignment measurements using an alignment sensor AS and/or level (height, tilt, etc.) measurements using a level sensor LS may be made.

The lithographic apparatus may also be of a type wherein at least a portion of the substrate may be covered by a liquid having a relatively high refractive index, e.g. water, to fill a space between the projection system and the substrate. An immersion liquid may also be applied to other spaces in the lithographic apparatus, for example, between the patterning device and the projection system. Immersion techniques are well known in the art for increasing the numerical aperture of projection systems. The term “immersion” as used herein does not mean that a structure, such as a substrate, must be submerged in liquid, but rather only means that liquid is located between the projection system and the substrate during exposure.

In operation of the lithographic apparatus, a radiation beam is conditioned and provided by the illumination system IL. The radiation beam B is incident on the patterning device (e.g., mask) MA, which is held on the support structure (e.g., mask table) MT, and is patterned by the patterning device. Having traversed the patterning device MA, the radiation beam B passes through the projection system PS, which focuses the beam onto a target portion C of the substrate W. With the aid of the second positioner PW and position sensor IF (e.g. an interferometric device, linear encoder, 2-D encoder or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above-described modes of use or entirely different modes of use may also be employed.

The substrate may be processed, before or after exposure, in for example a track (a tool that typically applies a layer of resist to a substrate and develops the exposed resist) or a metrology or inspection tool. Where applicable, the disclosure herein may be applied to such and other substrate processing tools. Further, the substrate may be processed more than once, for example in order to create a multi-layer IC, so that the term substrate used herein may also refer to a substrate that already includes multiple processed layers.

The terms “radiation” and “beam” used herein with respect to lithography encompass all types of electromagnetic radiation, including ultraviolet (UV) or deep ultraviolet (DUV) radiation (e.g. having a wavelength of 365, 248, 193, 157 or 126 nm) and extreme ultra-violet (EUV) radiation (e.g. having a wavelength in the range of 5-20 nm), as well as particle beams, such as ion beams or electron beams.

Various patterns on or provided by a patterning device may have different process windows. i.e., a space of processing variables under which a pattern will be produced within specification. Examples of pattern specifications that relate to potential systematic defects include checks for necking, line pull back, line thinning, CD, edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns.

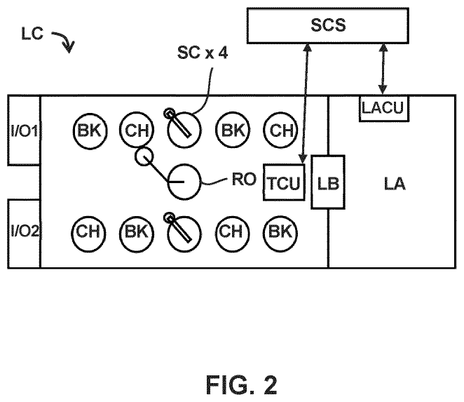

As shown in FIG. 2, the lithographic apparatus LA may form part of a lithographic cell LC, also sometimes referred to a lithocell or cluster, which also includes apparatuses to perform pre-and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc. Accordingly, a manufacturing facility in which lithocell LC is located also typically includes a metrology system that measures some or all of the substrates W (FIG. 1) that have been processed in the lithocell or other objects in the lithocell. The metrology system may be part of the lithocell LC, for example it may be part of the lithographic apparatus LA (such as alignment sensor AS (FIG. 1)).

The one or more measured parameters may include, for example, alignment, overlay

between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement is often performed on one or more dedicated metrology targets provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. A fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. Traditionally, this may be termed diffraction-based metrology. Applications of this diffraction-based metrology include the measurement of overlay, alignment, etc. For example, overlay and/or alignment can be measured by comparing parts of the diffraction spectrum (for example, comparing different diffraction orders in the diffraction spectrum of a periodic grating).

Thus, in a device fabrication process (e.g., a patterning process or a lithography process), a substrate or other objects may be subjected to various types of measurement during or after the process. The measurement may determine whether a particular substrate is defective, may establish adjustments to the process and apparatuses used in the process (e.g., aligning two layers on the substrate or aligning the patterning device to the substrate), may measure the performance of the process and the apparatuses, or may be for other purposes. Examples of measurement include optical imaging (e.g., optical microscope), non-imaging optical measurement (e.g., measurement based on diffraction such as the ASML YieldStar metrology tool, the ASML SMASH metrology system), mechanical measurement (e.g., profiling using a stylus, atomic force microscopy (AFM)), and/or non-optical imaging (e.g., scanning electron microscopy (SEM)). The SMASH (SMart Alignment Sensor Hybrid) system, as described in U.S. Pat. No. 6,961,116, which is incorporated by reference herein in its entirety, employs a self-referencing interferometer that produces two overlapping and relatively rotated images of an alignment marker, detects intensities in a pupil plane where Fourier transforms of the images are caused to interfere, and extracts the positional information from the phase difference between diffraction orders of the two images which manifests as intensity variations in the interfered orders.

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications. Other manufacturing process adjustments are contemplated.

A metrology system may be used to determine one or more properties of the substrate structure, and in particular, how one or more properties of different substrate structures vary, or different layers of the same substrate structure vary from layer to layer. The metrology system may be integrated into the lithographic apparatus LA or the lithocell LC, or may be a stand-alone device.

To enable the metrology, often one or more targets are specifically provided on the substrate. Typically, the target is specially designed and may comprise a periodic structure. For example, the target on a substrate may comprise one or more 1-D periodic structures (e.g., geometric features such as gratings), which are printed such that after development, the periodic structural features are formed of solid resist lines. As another example, the target may comprise one or more 2-D periodic structures (e.g., gratings), which are printed such that after development, the one or more periodic structures are formed of solid resist pillars or vias in the resist. The bars, pillars, or vias may alternatively be etched into the substrate (e.g., into one or more layers on the substrate).

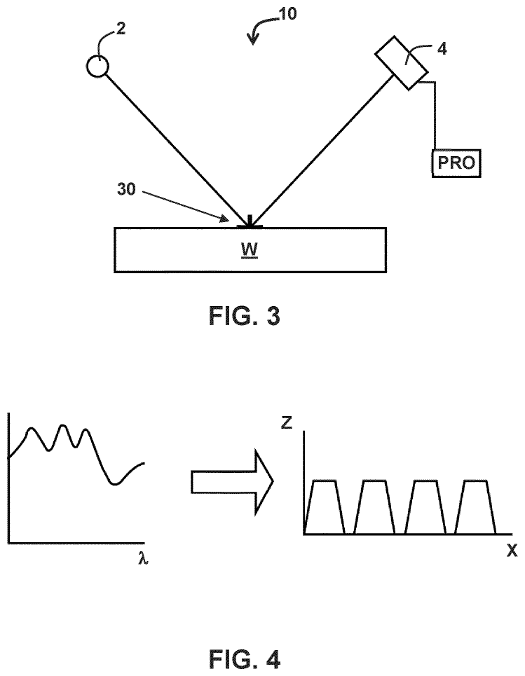

FIG. 3 depicts an example metrology (inspection) system 10 that may be used to detect overlay, alignment, and/or perform other metrology operations. It comprises a radiation or illumination source 2 which projects or otherwise irradiates radiation onto a substrate W (e.g., which may typically include a metrology mark). The redirected radiation is passed to a sensor such as a spectrometer detector 4 and/or other sensors, which measures a spectrum (intensity as a function of wavelength) of the specular reflected and/or diffracted radiation, as shown, e.g., in the graph on the left of FIG. 4. The sensor may generate a metrology signal conveying metrology data indicative of properties of the reflected radiation. From this data, the structure or profile giving rise to the detected spectrum may be reconstructed by one or more processors PRO, a generalized example of which is shown in FIG. 4, or by other operations.

As in the lithographic apparatus LA in FIG. 1, one or more substrate tables (not shown in FIG. 4) may be provided to hold the substrate W during measurement operations. The one or more substrate tables may be similar or identical in form to the substrate table WT (WTa or WTb or both) of FIG. 1. In an example where inspection system 10 is integrated with the lithographic apparatus, they may even be the same substrate table. Coarse and fine positioners may be provided and configured to accurately position the substrate in relation to a measurement optical system. Various sensors and actuators are provided, for example, to acquire the position of a target portion of interest of a structure (e.g., a metrology mark), and to bring it into position under an objective lens. Typically, many measurements will be made on target portions of a structure at different locations across the substrate W. The substrate support can be moved in X and Y directions to acquire different targets, and in the Z direction to obtain a desired location of the target portion relative to the focus of the optical system. It is convenient to think and describe operations as if the objective lens is being brought to different locations relative to the substrate, when, for example, in practice the optical system may remain substantially stationary (typically in the X and Y directions, but perhaps also in the Z direction) and the substrate moves. Provided the relative position of the substrate and the optical system is correct, it does not matter in principle which one of those is moving, or if both are moving, or a combination of a part of the optical system is moving (e.g., in the Z and/or tilt direction) with the remainder of the optical system being stationary and the substrate is moving (e.g., in the X and Y directions, but also optionally in the Z and/or tilt direction).

For typical metrology measurements, a target (portion) 30 on substrate W may be a 1-D grating, which is printed such that after development, the bars are formed of solid resist lines (e.g., which may be covered by a deposition layer), and/or other materials. Or the target 30 may be a 2-D grating, which is printed such that after development, the grating is formed of solid resist pillars, and/or other features in the resist.

The bars, pillars, vias, and/or other features may be etched into or on the substrate (e.g., into one or more layers on the substrate), deposited on a substrate, covered by a deposition layer, and/or have other properties. Target (portion) 30 (e.g., of bars, pillars, vias, etc.) is sensitive to changes in processing in the patterning process (e.g., optical aberration in the lithographic projection apparatus such as in the projection system, focus change, dose change, etc.) such that process variation manifests in variation in target 30. Accordingly, the measured data from target 30 may be used to determine an adjustment for one or more of the manufacturing processes, and/or used as a basis for making the actual adjustment.

For example, the measured data from target 30 may indicate overlay for a layer of a semiconductor device. The measured data from target 30 may be used (e.g., by the one or more processors PRO and/or other processors) for determining one or more semiconductor device manufacturing process parameters based the overlay, and determining an adjustment for a semiconductor device manufacturing apparatus based on the one or more determined semiconductor device manufacturing process parameters. In some embodiments, this may comprise a stage position adjustment, for example, or this may include determining an adjustment for a mask design, a metrology target design, a semiconductor device design, an intensity of the radiation, an incident angle of the radiation, a wavelength of the radiation, a pupil size and/or shape, a resist material, and/or other process parameters.

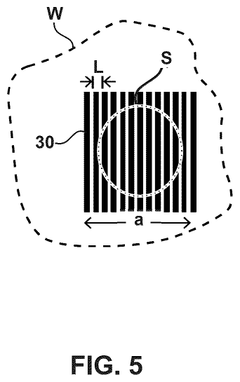

FIG. 5 illustrates a plan view of a typical target (e.g., metrology mark) 30, and the extent of a typical radiation illumination spot S in the system of FIG. 4. Typically, to obtain a diffraction spectrum that is free of interference from surrounding structures, the target 30, in an embodiment, is a periodic structure (e.g., grating) larger than the width (e.g., diameter) of the illumination spot S. The width of spot S may be smaller than the width and length of the target. The target, in other words, is ‘underfilled’ by the illumination, and the diffraction signal is essentially free from any signals from product features and the like outside the target itself. The illumination arrangement may be configured to provide illumination of a uniform intensity across a back focal plane of an objective, for example. Alternatively, by, for example, including an aperture in the illumination path, illumination may be restricted to on axis or off axis directions.

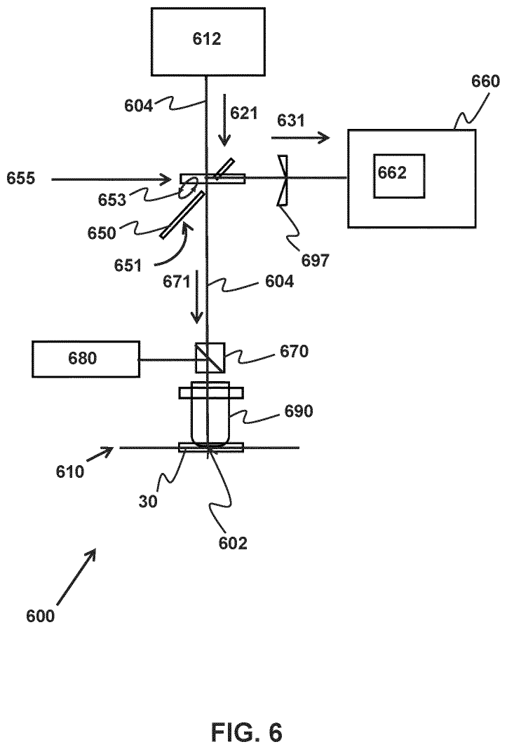

FIG. 6 illustrates a system 600 configured for generating one or more spots 602 of radiation 604 configured to be directed at one or more metrology targets 30 such as one or more diffraction grating targets. The radiation may be used to obtain images of the metrology targets, and/or for other uses. Radiation 604 may comprise illumination such as light and/or other radiation. A target 30 may comprise one or more metrology marks, such as diffraction grating targets, formed in a substrate such as a semiconductor wafer 610, for example. System 600 may form a portion of system 10 described above with respect to FIG. 3. System 600 may be a subsystem of system 10, for example. In some embodiments, one or more components of system 600 may be similar to and/or the same as one or more components of system 10. In some embodiments, one or more components of system 600 may replace, be used with, and/or otherwise augment one or more components of system 10. System 600 is configured to generate multiple spots of radiation from a radiation source 612 (e.g., similar to and/or the same as source 2 shown in FIG. 3).

As described above, system 600 is configured to eliminate a need for a quad non-polarizing beam splitter, and therefore a need for (e.g., overlay or alignment) image stitching, among other advantages. Prior metrology systems used a quad non-polarizing beam splitter to enhance an intensity of radiation (e.g., increase a number of photons) transmitted to a target such as a metrology mark, to facilitate faster image acquisition, for example. However, image stitching is required if a quad non-polarizing beam splitter is used, because the quad non-polarizing beam splitter is in a common path with the alignment branch and not located at a pupil plane of the system. The non-pupil plane location causes defocusing and/or radiation intensity inhomogeneity issues, and results in acquisition of something less than a full field of view of a metrology target for alignment purposes, for example. Image stitching introduces (e.g., alignment) error, which is not desired, and negatively impacts the ability of these prior metrology systems to meet future (e.g., alignment and/or various critical dimension (CD)) specifications.

In more detail, prior quad non-polarizing beam splitters were designed for optimizing a zero-order reflection and first-order transmission in order to achieve a >3× radiation transmission gain for a metrology sensor. The concept was realized with a patterned coating, which provided transmissive and reflective portions simultaneously. However, the quad non-polarizing beam splitters were in a common path with the alignment branch and not located at the pupil plane in these systems, which resulted in a critical impact on the intensity homogeneity of sensed images. As a result, only partial fields of view in the images could be applied. In order to obtain a full field of view, multiple images and stitching was required. Stitching error from the intensity inhomogeneity was shown to cause up to a 20 μm wafer position error.

In addition, if a prior metrology system used a wedge or other similar optical components to separate radiation reflected from a target, a quad non-polarizing beam splitter (not located in a pupil plane) caused such radiation to spread into “safety zones” meant to prevent overlap between portions of diffracted and reflected radiation. To overcome this issue, in prior metrology systems, safety zone sizes were typically increased, and/or transmission aperture sizes and/or shapes were adjusted, which further reduced a corresponding field of view for alignment purposes, and increased a likelihood of stitching related errors.

For radiation detection in prior metrology systems, there was a transmission safety zone around the boarder of the reflective and transmissive portions of the coating in the quad non-polarizing beam splitters due to the fact that wedges and the quad non-polarizing beam splitters were not optically conjugated in prior systems. Thus, if first order diffracted radiation overlapped with a transmission safety zone, it could impact the accuracy of an overlay measurement, for example. To prevent this accuracy impact, smaller illumination mode selector apertures were be used in an attempt to avoid the overlap, but this cost illumination light intensity and/or system throughput (which the quad non-polarizing beam splitter was originally intended to improve).

System 600 provides a new optical design architecture. Instead of a quad non-polarizing beam splitter, shaped apertures and corresponding reflective portions are provided on an optical element 650 (an illumination mode selector), which is positioned in the pupil plane of system 600. This architecture still enhances the intensity of radiation (e.g., increases a number of photons) transmitted to a target such as a metrology mark, to facilitate faster image acquisition, for example, but without requiring image stitching. System 600 may reduce costs compared to prior systems because the quad non-polarizing beam splitter and/or other additional optical components are removed compared to previous designs. With system 600, alignment position error is reduced or eliminated because a full field of view may be obtained, without a need for image stitching that often causes (e.g., alignment) errors. System 600 enhances throughput compared to prior systems because an illumination mode selector and wedge safety zone can be minimized, while a relatively large illumination mode selector aperture can still be applied and optimized for illumination intensity. System 600 also still allows different illumination patterns for various metrology applications. Other advantages are contemplated.

System 600 comprises radiation source 612; an optical element 650; a detection branch 660 with a detector 662; a beam splitter 670; an alignment branch 680; various lenses, reflectors, and other optical components (with an example objective lens 690 labeled in FIG. 6); and/or other components. In some embodiments, the components of system 600 form a portion of an overlay and/or alignment sensor that is used in a semiconductor manufacturing process. In some embodiments, system 600 may have other uses including, for example, in any metrology system that requires multiple radiation spots on a target generated from a single radiation beam.

Radiation source 612 is configured to generate radiation along a first optical path 621. The radiation may have a target wavelength and/or wavelength range, a target intensity, and/or other characteristics. The target wavelength and/or wavelength range, the target intensity, etc., may be entered and/or selected by a user, determined by the system (e.g., system 10 shown in FIG. 3) based on previous measurements, and/or determined in other ways. In some embodiments, the radiation comprises light and/or other radiation. In some embodiments, the light comprises visible light, infrared light, near infrared light, and/or other light. In some embodiments, the radiation may be any radiation appropriate for interferometry.

Optical element 650 is configured to replace a quad non polarizing beam splitter in prior metrology systems. Optical element 650 is configured to be positioned in a pupil plane 655 of system 100 (e.g., to mitigate problems with prior metrology systems described above). Optical element 650 is configured to receive radiation from radiation source 612 along first optical path 621, and transmit portions of the radiation through the transmissive portions of the at least one multi-aperture pattern toward a target 30. Target 30 may be one or more metrology marks such as diffraction grating targets on a semiconductor wafer, as described herein, for example, collectively referred to as target 30. Target 30 may comprise one or more structures in the patterned substrate capable of providing a diffraction signal. One or more targets 30 may be included in a layer of a substrate in a semiconductor device structure, for example. In some embodiments, the feature comprises a geometric feature such as a 1D or 2D feature, and/or other geometric features. By way of several non-limiting examples, the feature may comprise a grating, a line, an edge, a fine-pitched series of lines and/or edges, and/or other features.

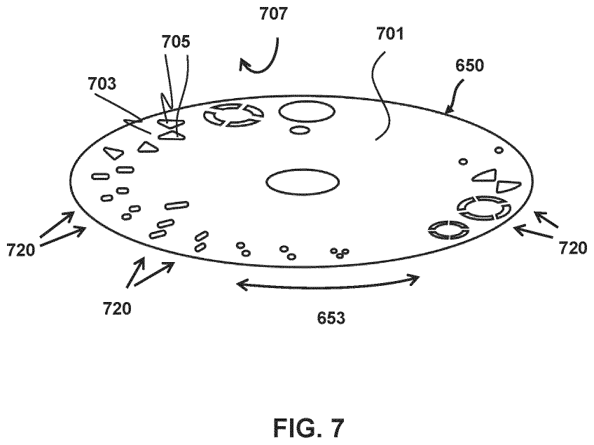

FIG. 7 illustrates an example of optical element 650. Optical element 650 comprises a body 701, at least one multi-aperture pattern 703 with transmissive portions 705 and reflective portions 707 (e.g., on an underside of body 701), and/or other components. In some embodiments, optical element 650 is an illumination mode selector. The illumination mode selector is movable 653 to facilitate selection of the at least one multi-aperture pattern 703 from among other different possible multi-aperture patterns 720. In some embodiments, as shown in FIG. 7, the illumination mode selector is a rotatable wheel with the at least one multi-aperture pattern 703 and the other different possible multi-aperture patterns 720 formed therein.

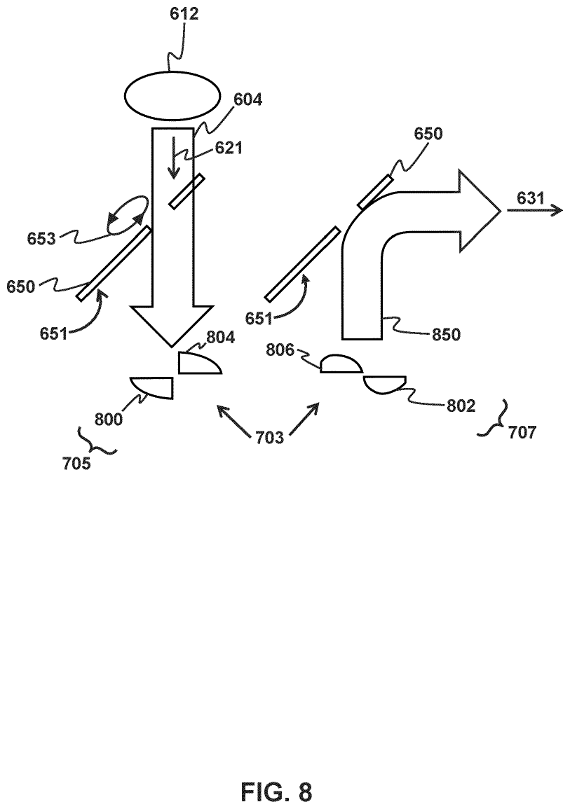

FIG. 8 illustrates the at least one multi-aperture pattern 703 comprising four quadrants 800, 802, 804, and 806. First and third opposing quadrants 800 and 804 comprise two opposing apertures forming transmissive portions 705, and second and fourth opposing quadrants 802 and 806 comprise reflective portions 707 of the at least one multi-aperture pattern 703. In some embodiments, the at least one multi-aperture pattern 703 comprises opposing apertures (in quadrants 800 and 804) that form transmissive portions 705, with each opposing aperture comprising an orifice shaped as a sector of a circle (as shown in FIG. 8). This example shape is configured based on other optical components in a metrology sensor such as an objective lens and/or a wedge, for example. In this case, opposing transmissive quadrants are needed, but the specific sector shapes are not strictly necessary. For example, other shapes such as squares, etc., are contemplated (as can be seen in FIG. 7).

The two transmissive apertures in quadrants 800 and 804 form transmissive portions 705 of the at least one multi-aperture pattern 703. The transmissive apertures in the two opposing quadrants 800 and 804 are configured to split radiation 604 into a first sub-beam and a second sub-beam, and direct the first sub-beam and the second sub-beam toward target(s) 30 (FIG. 6). In some embodiments, about 50% of radiation 604 is transmitted through the two transmissive apertures in quadrants 800 and 804 of the at least one multi-aperture pattern 703. In some embodiments, about 30%, 40%, 60%, 70%, 80%, or 90% of radiation 604 is transmitted.

Optical element 650 reflects, with reflective portions 707 (quadrants 802 and 806) of the at least one multi-aperture pattern 703, diffracted radiation 850 from a diffraction grating target 30 along optical path 631 toward detector 662 (FIG. 6). In some embodiments, reflective portions 707 are formed by coating a reflective coating (e.g., gold, silver, etc.) on select portions of the body of optical element 650. Multi-layer dielectric coatings may also be used, for example. These can be patterned and added by lithography techniques with sputtering, thermal evaporation coating, and/or other techniques.

Returning to FIG. 6, in some embodiments, reflective portions 707 (FIG. 7 and FIG. 8) of optical element 650 are configured to reflect diffracted plus and minus first order radiation through detector branch 660 of system 600 along optical path 631 to detector 662. Detector 662 is configured to receive the diffracted first order radiation and generate a detection signal (e.g., as described above related to FIG. 3-5). This may include generating and/or analyzing one or more images of a target 30, using the radiation described herein. The plus and minus first diffraction order diffracted radiation from diffraction grating target(s) 30 is reflected by the two reflective quadrants 802 and 806 (FIG. 8) of the at least on multi-aperture pattern 703 (FIG. 7). The two reflective quadrants 802 and 806 are located on a back or non-radiation source facing side 651 of optical element 650. The two reflective quadrants 802 and 806 form reflective portions 707 (FIG. 7 and FIG. 8) of the at least one multi-aperture pattern 703.

Alignment branch 680 is configured to receive reflected radiation and generate an alignment signal (e.g., as described above related to FIG. 3-5). This may include generating and/or analyzing one or more images of a target 30, using the radiation described herein. Beam splitter 670 is an alignment branch 680 beam splitter configured to transmit transmitted radiation 671 from the transmissive portions of the at least one multi-aperture pattern. In some embodiments, alignment branch 680 beam splitter 670 is a transmissive optic cube, for example. As shown in FIG. 6, alignment branch 680 beam splitter 670 is positioned between optical element 650 and diffraction grating target 30. This ensures that optical element 650 is not coupled to alignment branch 680 and alignment branch 680 beam splitter 670 is not in a common path with detector branch 660. This is advantageous at least because, since optical element 650 is conjugated to the pupil plane and is not in a common path with alignment branch 680, system 600 does not suffer from the image stitching and error issues observed in prior metrology systems (e.g., as described above).

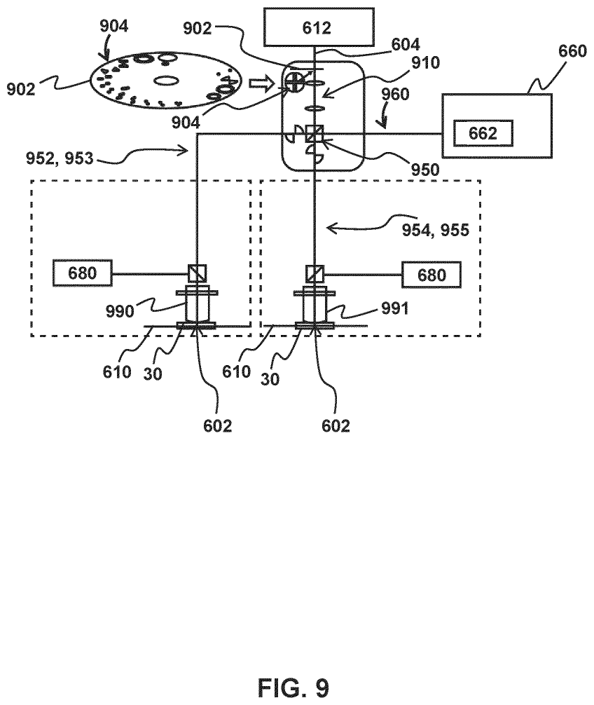

System 600 may take alternate forms. One such alternate form is illustrated in FIG. 9 as system 900. System 900 is configured such that radiation from radiation source 612 is received with an optical element 902 (e.g., similar to optical element 650 described above) formed by a rotatable disk comprising at least one multi-aperture pattern 904. Optical element 902 is positioned in a pupil plane of system 900. Optical element 902 transmits portions of radiation 604 through transmissive portions of the at least one multi-aperture pattern 904 and a relay lens pair 910 toward a diffraction grating target 30 (or targets 30). In contrast to system 600 shown in FIG. 6, system 900 is configured to transmit, with a second optical element 950 comprising a quad beam splitter with transmissive portions and reflective portions, a first portion 952 of radiation received from optical element 902 along a first optical path 953, and a second portion 954 of the radiation along a second optical path 955, toward the diffraction grating target(s) 30. System 900 is configured to focus corresponding spots 602 of radiation on diffraction grating target(s) 30. The reflective portions of the quad beam splitter are configured to reflect diffracted radiation from the diffraction grating target along a third optical path 960 toward detector 662.

Referring to FIG. 6 and FIG. 9, the various lenses (example objective lens 690 is labeled in FIGS. 6; and 990 and 991 are labeled in FIG. 9), reflectors, and other optical components (e.g. such as a wedge 697) are configured to receive, transmit, reflect, focus, and/or perform other operations on the illumination generated by illumination source 612, split by beam splitter 670 (FIG. 6), transmitted or reflected by optical element 650 (FIG. 6) and/or 902, 950 (FIG. 9), received by detection branch 660, received by alignment branch(es) 680, and/or used by other portions of system 600 and/or 900. These various lenses, reflectors, and/or other optical components may comprise any type of lens, reflector, and/or other optical component configured to allow system 600 and/or 900 to function as described. For example, objective lenses 690, 990, and/or 991 may be formed from any transparent material and have curved surfaces configured to concentrate or otherwise focus one or more spots 602 of radiation on target(s) 30. The various lenses, reflectors, optical elements 650, 902, and/or 950, beam splitter 670, and other optical elements may be positioned in any location and/or at any angle relative to each other that allows system 600 and/or system 900 to function as described herein. This may include positioning at specific relative distances between elements, specific angles between elements, etc. In some embodiments, the various lenses, reflectors, optical elements, beam splitters, and other optical components are positioned relative to each other in system 600 and/or system 900 via structural members, clips, clamps, screws, nuts, bolts, adhesive, and/or other mechanical devices. In some embodiments, various ones of the lenses, reflectors, optical elements, beam splitters, and other optical elements are movable relative to each other. Movement may be configured to adjust locations of corresponding spots of illumination on one or more targets 30, for example. In some embodiments, movement comprises tilting, translating or otherwise changing a distance between various lenses, reflectors, and other optical components. Other examples of movement are contemplated.

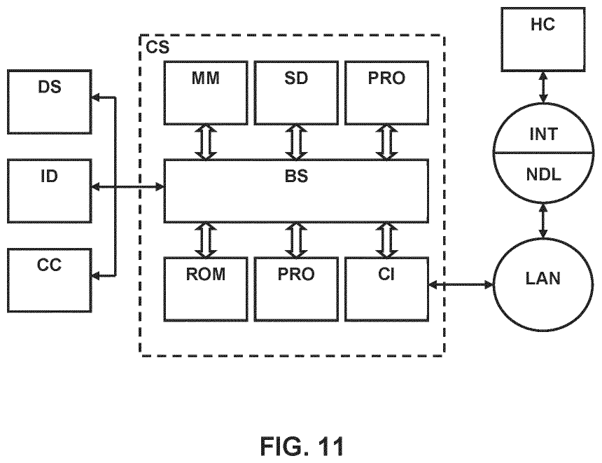

In some embodiments, movement may be controlled electronically by a processor, such as processor PRO shown in FIG. 3 (and also in FIG. 11 discussed below). Processor PRO may be included in a computing system CS (FIG. 11) and may operate based on computer or machine readable instructions MRI (e.g., as described below related to FIG. 11). Electronic communication may occur by transmitting electronic signals between separate components, transmitting data between separate components of system 600 and/or system 900, transmitting values between separate components, and/or other communication. The components of system 600 and/or system 900 may communicate via wires or wirelessly via a network, such as the Internet or the Internet in combination with various other networks, like local area networks, cellular networks, or personal area networks, internal organizational networks, and/or other networks.

In some embodiments, one or more actuators (not shown in FIG. 6 or FIG. 9) may be coupled to and configured to move one or more components of system 600 and/or system 900. The actuators may be coupled to one or components of system 600 and/or system 900 by adhesive, clips, clamps, screws, a collar, and/or other mechanisms. The actuators may be configured to be controlled electronically. Individual actuators may be configured to convert an electrical signal into mechanical displacement. The mechanical displacement is configured to move a component of system 600 and/or system 900. As an example, one or more of the actuators may be piezoelectric. One or more processors PRO may be configured to control the actuators. One or more processors PRO may be configured to individually control each of the one or more actuators.

The quantity of the various lenses, reflectors, and/or other optical components shown in FIG. 6 and/or FIG. 9 is not intended to be limiting. The principles described herein may be extended such that, in some embodiments system 600 and/or system 900 comprises additional or fewer lenses, reflectors, and/or other optical components

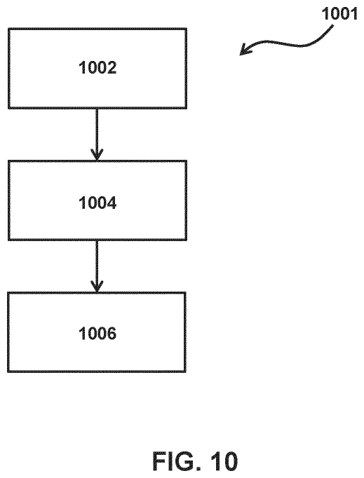

FIG. 10 illustrates a metrology method 1001 for generating spots of illumination configured to be directed at a target. In some embodiments, method 1001 is performed as part of an overlay and/or alignment sensing operation in a semiconductor device manufacturing process, for example. In some embodiments, one or more operations of method 1001 may be implemented in or by system 600 illustrated in FIG. 6, system 900 shown in FIG. 9, system 10 illustrated in FIG. 3, a computer system (e.g., as illustrated in FIG. 11 and described below), and/or in or by other systems, for example. In some embodiments, method 1001 comprises receiving (operation 1002), with a first optical element, illumination from an illumination source, reflecting (operation 1004) diffracted radiation from a diffraction grating target, determining (operation 1006) overlay and/or alignment based on reflected diffracted radiation from the diffraction grating target, and/or other operations.

The operations of method 1001 are intended to be illustrative. In some embodiments, method 1001 may be accomplished with one or more additional operations not described, and/or without one or more of the operations discussed. For example, in some embodiments, method 1001 may include an additional operation comprising determining an adjustment for a semiconductor device manufacturing process. Additionally, the order in which the operations of method 1001 are illustrated in FIG. 10 and described herein is not intended to be limiting.

In some embodiments, one or more portions of method 1001 may be implemented in and/or controlled by one or more processing devices (e.g., a digital processor, an analog processor, a digital circuit designed to process information, an analog circuit designed to process information, a state machine, and/or other mechanisms for electronically processing information). The one or more processing devices may include one or more devices executing some or all of the operations of method 1001 in response to instructions stored electronically on an electronic storage medium. The one or more processing devices may include one or more devices configured through hardware, firmware, and/or software to be specifically designed for execution of one or more of the operations of method 1001 (e.g., see discussion related to FIG. 11 below).

At operation 1002, radiation is received from a radiation source along a first optical path, and portions of the radiation are transmitted through transmissive portions of at least one multi-aperture pattern toward a diffraction grating target. The at least one multi-aperture pattern is formed in an optical element. The at least one multi-aperture pattern comprises the transmissive portions and reflective portions. The optical element is positioned in a pupil plane of a metrology system. About 50% of the radiation is transmitted through two transmissive quadrants of the at least one multi-aperture pattern. The two transmissive quadrants form the transmissive portions of the at least one multi-aperture pattern. In some embodiments, the at least one multi-aperture pattern comprises four quadrants, with first and third opposing quadrants comprising two opposing apertures forming the transmissive portions, and second and fourth opposing quadrants comprising the reflective portions of the at least one multi-aperture pattern. The two opposing (transmissive) apertures are configured to split the radiation into a first sub-beam and a second sub-beam, direct the first sub-beam through a first optical branch of the system to form a first spot, and direct the second sub-beam through a second optical branch of the system to form a second spot. In some embodiments, each opposing transmissive aperture comprises an orifice shaped as a sector of a circle. Other shapes that facilitate the performance of method 1001 as described are contemplated.

In some embodiments, the optical element is an illumination mode selector. The illumination mode selector is movable to facilitate selection of the at least one multi-aperture pattern from among other different possible multi-aperture patterns. For example, the illumination mode selector may be a rotatable wheel with the at least one multi-aperture pattern and the other different possible multi-aperture patterns formed therein. As described above, the illumination mode selector is configured to replace a quad non polarizing beam splitter in prior metrology systems.

In some embodiments, the optical element is the same as or similar to element 650 shown in FIG. 6 and described above. In some embodiments, operation 1002 comprises providing the illumination source (e.g., source 2 shown in FIG. 3). The illumination source comprises a single source configured to generate the illumination along the first axis.

At operation 1004 diffracted radiation from a diffraction grating target is reflected, with the reflective portions of the at least one multi-aperture pattern, along a second optical path toward a detector. Plus and minus first diffraction order diffracted radiation from the diffraction grating target is reflected by two reflective quadrants of the at least on multi-aperture pattern. The two reflective quadrants are located on a back or non-radiation source facing side of the optical element. The two reflective quadrants form the reflective portions of the at least one multi-aperture pattern. The reflective portions may be formed by coating a reflective coating (such as gold, silver, etc.) on select portions (e.g., the two opposing reflective quadrants as described above) of a body of the optical element.

The reflective portions are configured to reflect diffracted plus and minus first order radiation through a detector branch of the system along an optical path to a detector. The detector is configured to receive the diffracted first order radiation and generate a detection signal. This may be an overlay (or alignment in some embodiments) signal, for example. In some embodiments, operation 1004 is performed by an optical element is the same as or similar to optical element 650 shown in FIG. 6 and described above.

In some embodiments, method 1001 comprises transmitting, with an alignment branch beam splitter, transmitted radiation from the transmissive portions of the at least one multi-aperture pattern. The alignment branch beam splitter is not in a common path with a detector branch of the system. The alignment branch beam splitter may be a transmissive optic cube, for example. The alignment branch beam splitter is positioned between the optical element and the diffraction grating target, such that the optical element is not coupled to the alignment branch.

In some embodiments operations 1002 and 1004 may instead comprise: (operation 1002) receiving radiation from the radiation source with a first optical element formed by a rotatable disk comprising at least one multi-aperture pattern, where the first optical element is positioned in a pupil plane of the system; and transmitting portions of the radiation through transmissive portions of the at least one multi-aperture pattern and a relay lens pair toward a diffraction grating target; and (operation 1004) transmitting, with a second optical element comprising a quad beam splitter with transmissive portions and reflective portions, a first portion of radiation received from the first optical element along a first optical path, and a second portion of the radiation along a second optical path, toward the diffraction grating target; and focusing corresponding spots of radiation on the diffraction grating target, where the reflective portions of the quad beam splitter are configured to reflect diffracted radiation from the diffraction grating target along a third optical path toward a detector (see FIG. 9 and the corresponding description above).

At operation 1006, overlay and/or alignment are determined. Overlay and/or alignment are determined based on reflected diffracted radiation from the diffraction grating target and/or other information. In some embodiments, operation 1006 is performed by a detector the same as or similar to detector 4 and processor PRO shown in FIG. 3 and described above, and/or the detector and/or alignment branches described above related to FIG. 6 and/or FIG. 9.

In some embodiments, method 1001 includes illuminating (and/or otherwise irradiating) one or more targets (e.g., targets 30 shown in FIG. 3, FIG. 6, and FIG. 9) in a patterned substrate with radiation. The radiation comprises light and/or other radiation separated into illumination spots as described above.

The radiation may be generated by a radiation source (e.g., source 2 shown in FIG. 3, and/or source 612 in FIG. 6 and FIG. 9, and described above). In some embodiments, the radiation may be directed by the radiation source onto multiple targes, a single target, sub-portions (e.g., something less than the whole) of a target, and/or onto a substrate in other ways. In some embodiments, the radiation may be directed by the radiation source onto the target in a time varying manner. For example, the radiation may be rastered over a target (e.g., by moving the target under the radiation) such that different portions of the target are irradiated at different times. As another example, characteristics of the radiation (e.g., wavelength, intensity, etc.) may be varied. This may create time varying data envelopes, or windows, for analysis. The data envelopes may facilitate analysis of individual sub-portions of a target, comparison of one portion of a target to another and/or to other targets (e.g., in other layers), and/or other analysis.

In some embodiments, method 1001 comprises detecting reflected radiation from one or more diffraction grating targets. Detecting reflected radiation comprises detecting one or more phase and/or amplitude (intensity) shifts in reflected radiation from one or more geometric features of the target(s). The one or more phase and/or amplitude shifts correspond to one or more dimensions of a target. For example, the phase and/or amplitude of reflected radiation from one side of a target is different relative to the phase and/or amplitude of reflected radiation from another side of the target.

Detecting the one or more phase and/or amplitude (intensity) shifts in the reflected radiation from the target comprises measuring local phase shifts (e.g., local phase deltas) and/or amplitude variations that correspond to different portions of a target. For example, the reflected radiation from a specific area of a target may comprise a sinusoidal waveform having a certain phase and/or amplitude. The reflected radiation from a different area of the target (or a target in a different layer) may also comprise a sinusoidal waveform, but one with a different phase and/or amplitude. Detected reflected radiation also comprises measuring a phase and/or amplitude difference in reflected radiation of different diffraction orders. Detecting the one or more local phase and/or amplitude shifts may be performed using Hilbert transformations, for example, and/or other techniques. Interferometry techniques and/or other operations may be used to measure phase and/or amplitude differences in reflected radiation of different diffraction orders.

In some embodiments, method 1001 comprises generating a metrology signal based on the detected reflected radiation from diffraction grating target(s), as described above. The metrology signal is generated by a sensor (such as detector 4 in FIG. 3, a camera, and/or other sensors) based on radiation received by the sensor. The metrology signal comprises measurement information pertaining to the target(s). For example, the metrology signal may be an overlay and/or alignment signal comprising overlay and/or alignment measurement information, and/or other metrology signals. The measurement information (e.g., an overlay value, an alignment value, and/or other information) may be determined using principles of interferometry and/or other principles.

The metrology signal comprises an electronic signal that represents and/or otherwise corresponds to the radiation reflected from the target(s). The metrology signal may indicate a metrology value associated with a diffraction grating target, for example, and/or other information. Generating the metrology signal comprises sensing the reflected radiation and converting the sensed reflected radiation into the electronic signal. In some embodiments, generating the metrology signal comprises sensing different portions of the reflected radiation from different areas and/or different geometries of the target, and/or multiple targets, and combining the different portions of the reflected radiation to form the metrology signal. This may include generating and/or analyzing one or more images of a target, using the radiation described herein. This sensing and converting may be performed by components similar to and/or the same as detector 4 and/or processors PRO shown in FIG. 3, and/or other components.

In some embodiments, method 1001 comprises determining an adjustment for a semiconductor device manufacturing process. In some embodiments, method 1001 includes determining one or more semiconductor device manufacturing process parameters. The one or more semiconductor device manufacturing process parameters may be determined based on one or more detected phase and/or amplitude variations, an overlay and/or alignment value indicated by the metrology signal, and/or other similar systems, and/or other information. The one or more parameters may include a parameter of the radiation (the radiation used for metrology), an overlay value, an alignment value, a metrology inspection location on a layer of a semiconductor device structure, a radiation beam trajectory across a target, and/or other parameters. In some embodiments, process parameters can be interpreted broadly to include a stage position, a mask design, a metrology target design, a semiconductor device design, an intensity of the radiation (used for exposing resist, etc.), an incident angle of the radiation (used for exposing resist, etc.), a wavelength of the radiation (used for exposing resist, etc.), a pupil size and/or shape, a resist material, and/or other parameters.

In some embodiments, method 1001 includes determining a process adjustment based on the one or more determined semiconductor device manufacturing process parameters, adjusting a semiconductor device manufacturing apparatus based on the determined adjustment, and/or other operations. For example, if a determined metrology measurement is not within process tolerances, the out of tolerance measurement may be caused by one or more manufacturing processes whose process parameters have drifted and/or otherwise changed so that the process is no longer producing acceptable devices (e.g., measurements may breach a threshold for acceptability). One or more new or adjusted process parameters may be determined based on the measurement determination. The new or adjusted process parameters may be configured to cause a manufacturing process to again produce acceptable devices.

For example, a new or adjusted process parameter may cause a previously unacceptable measurement value to be adjusted back into an acceptable range. The new or adjusted process parameters may be compared to existing parameters for a given process. If there is a difference, that difference may be used to determine an adjustment for an apparatus that is used to produce the devices (e.g., parameter “x” should be increased/decreased/changed so that it matches the new or adjusted version of parameter “x” determined as part of method 1001), for example. In some embodiments, method 1001 may include electronically adjusting an apparatus (e.g., based on the determined process parameters). Electronically adjusting an apparatus may include sending an electronic signal, and/or other communications to the apparatus, for example, which causes a change in the apparatus. The electronic adjustment may include changing a setting on the apparatus, for example, and/or other adjustments.

FIG. 11 is a diagram of an example computer system CS that may be used for one or more of the operations described herein. Computer system CS includes a bus BS or other communication mechanism for communicating information, and a processor PRO (or multiple processors similar to and/or the same as processor PRO shown in FIG. 3) coupled with bus BS for processing information. Computer system CS also includes a main memory MM, such as a random access memory (RAM) or other dynamic storage device, coupled to bus BS for storing information and instructions to be executed by processor PRO. Main memory MM also may be used for storing temporary variables or other intermediate information during execution of instructions by processor PRO. Computer system CS further includes a read only memory (ROM) ROM or other static storage device coupled to bus BS for storing static information and instructions for processor PRO. A storage device SD, such as a magnetic disk or optical disk, is provided and coupled to bus BS for storing information and instructions.

Computer system CS may be coupled via bus BS to a display DS, such as a flat panel or touch panel display or a cathode ray tube (CRT) for displaying information to a computer user. An input device ID, including alphanumeric and other keys, is coupled to bus BS for communicating information and command selections to processor PRO. Another type of user input device is cursor control CC, such as a mouse, a trackball, or cursor direction keys for communicating direction information and command selections to processor PRO and for controlling cursor movement on display DS. This input device typically has two degrees of freedom in two axes, a first axis (e.g., x) and a second axis (e.g., y), that allows the device to specify positions in a plane. A touch panel (screen) display may also be used as an input device.

In some embodiments, all or some of one or more operations described herein may be performed by computer system CS in response to processor PRO executing one or more sequences of one or more instructions contained in main memory MM. Such instructions may be read into main memory MM from another computer-readable medium, such as storage device SD. Execution of the sequences of instructions included in main memory MM causes processor PRO to perform the process steps (operations) described herein. One or more processors in a multi-processing arrangement may also be employed to execute the sequences of instructions contained in main memory MM. In some embodiments, hard-wired circuitry may be used in place of or in combination with software instructions. Thus, the description herein is not limited to any specific combination of hardware circuitry and software.

The term “computer-readable medium” or “machine-readable medium” as used herein refers to any medium that participates in providing instructions to processor PRO for execution. Such a medium may take many forms, including but not limited to, non-volatile media, volatile media, and transmission media. Non-volatile media include, for example, optical or magnetic disks, such as storage device SD. Volatile media include dynamic memory, such as main memory MM. Transmission media include coaxial cables, copper wire and fiber optics, including the wires that comprise bus BS. Transmission media can also take the form of acoustic or light waves, such as those generated during radio frequency (RF) and infrared (IR) data communications. Computer-readable media can be non-transitory, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. Non-transitory computer readable media can have instructions recorded thereon. The instructions, when executed by a computer, can implement any of the operations described herein. Transitory computer-readable media can include a carrier wave or other propagating electromagnetic signal, for example.

Various forms of computer readable media may be involved in carrying one or more sequences of one or more instructions to processor PRO for execution. For example, the instructions may initially be borne on a magnetic disk of a remote computer. The remote computer can load the instructions into its dynamic memory and send the instructions over a telephone line using a modem. A modem local to computer system CS can receive the data on the telephone line and use an infrared transmitter to convert the data to an infrared signal. An infrared detector coupled to bus BS can receive the data carried in the infrared signal and place the data on bus BS. Bus BS carries the data to main memory MM, from which processor PRO retrieves and executes the instructions. The instructions received by main memory MM may optionally be stored on storage device SD either before or after execution by processor PRO.

Computer system CS may also include a communication interface CI coupled to bus BS. Communication interface CI provides a two-way data communication coupling to a network link NDL that is connected to a local network LAN. For example, communication interface CI may be an integrated services digital network (ISDN) card or a modem to provide a data communication connection to a corresponding type of telephone line. As another example, communication interface CI may be a local area network (LAN) card to provide a data communication connection to a compatible LAN. Wireless links may also be implemented. In any such implementation, communication interface CI sends and receives electrical, electromagnetic or optical signals that carry digital data streams representing various types of information.

Network link NDL typically provides data communication through one or more networks to other data devices. For example, network link NDL may provide a connection through local network LAN to a host computer HC. This can include data communication services provided through the worldwide packet data communication network, now commonly referred to as the “Internet” INT. Local network LAN (Internet) may use electrical, electromagnetic or optical signals that carry digital data streams. The signals through the various networks and the signals on network data link NDL and through communication interface CI, which carry the digital data to and from computer system CS, are exemplary forms of carrier waves transporting the information.

Computer system CS can send messages and receive data, including program code, through the network(s), network data link NDL, and communication interface CI. In the Internet example, host computer HC might transmit a requested code for an application program through Internet INT, network data link NDL, local network LAN, and communication interface CI. One such downloaded application may provide all or part of a method described herein, for example. The received code may be executed by processor PRO as it is received, and/or stored in storage device SD, or other non-volatile storage for later execution. In this manner, computer system CS may obtain application code in the form of a carrier wave.

Various embodiments of the present systems and methods are disclosed in the subsequent list of numbered clauses. In the following, further features, characteristics, and exemplary technical solutions of the present disclosure will be described in terms of clauses that may be optionally claimed in any combination:
1. A metrology system, comprising: an optical element comprising at least one multi-aperture pattern with transmissive and reflective portions, the optical element positioned in a pupil plane of the system, the optical element configured to: receive radiation from a radiation source along a first optical path, and transmit portions of the radiation through the transmissive portions of the at least one multi-aperture pattern toward a diffraction grating target; and reflect, with the reflective portions of the at least one multi-aperture pattern, diffracted radiation from the diffraction grating target along a second optical path toward a detector.
2. The system of clause 1, wherein about 50% of the radiation is transmitted through two transmissive quadrants of the at least one multi-aperture pattern, the two transmissive quadrants forming the transmissive portions of the at least one multi-aperture pattern.
3. The system of any of the previous clauses, wherein plus and minus first diffraction order diffracted radiation from the diffraction grating target is reflected by two reflective quadrants of the at least on multi-aperture pattern, the two reflective quadrants located on a back or non-radiation source facing side of the optical element, the two reflective quadrants forming the reflective portions of the at least one multi-aperture pattern.
4. The system of any of the previous clauses, wherein the optical element is an illumination mode selector.
5. The system of any of the previous clauses, wherein the illumination mode selector is movable to facilitate selection of the at least one multi-aperture pattern from among other different possible multi-aperture patterns.
6. The system of any of the previous clauses, wherein the illumination mode selector is a rotatable wheel with the at least one multi-aperture pattern and the other different possible multi-aperture patterns formed therein.
7. The system of any of the previous clauses, wherein the at least one multi-aperture pattern comprises four quadrants, with first and third opposing quadrants comprising two opposing apertures forming the transmissive portions, and second and fourth opposing quadrants comprising the reflective portions of the at least one multi-aperture pattern.
8. The system of any of the previous clauses, wherein the two opposing apertures are configured to split the radiation into a first sub-beam and a second sub-beam, direct the first sub-beam through a first optical branch of the system to form a first spot, and direct the second sub-beam through a second optical branch of the system to form a second spot.
9. The system of any of the previous clauses, wherein the reflective portions are configured to reflect diffracted plus and minus first order radiation through a detector branch of the system along the second optical path to the detector; wherein the detector is configured to receive the diffracted first order radiation and generate a detection signal.
10. The system of any of the previous clauses, further comprising an alignment branch beam splitter configured to transmit transmitted radiation from the transmissive portions of the at least one multi-aperture pattern, wherein the alignment branch beam splitter is not in a common path with the detector branch.
11. The system of any of the previous clauses, wherein the alignment branch beam splitter is a transmissive optic cube.
12. The system of any of the previous clauses, wherein the alignment branch beam splitter is positioned between the optical element and the diffraction grating target, and wherein the optical element is not coupled to an alignment branch of the metrology system.
13. The system of any of the previous clauses, wherein the at least one multi-aperture pattern comprises two opposing apertures that form the transmissive portions, each opposing aperture comprising an orifice shaped as a sector of a circle.
14. The system of any of the previous clauses, wherein the optical element is configured to replace a quad non polarizing beam splitter in the metrology system.
15. The system of any of the previous clauses, wherein the reflective portions are formed by coating a reflective coating on select portions of an optical element body.
16. The system of any of the previous clauses, further comprising the radiation source, the radiation source configured to generate the radiation along the first optical path.
17. The system of any of the previous clauses, further comprising the detector, the detector configured to receive diffracted and reflected first order radiation from first and second illumination spots on diffraction grating targets and generate a detection signal.
18. The system of any of the previous clauses, wherein the optical element forms a portion of an alignment sensor and/or an overlay detection sensor.
19. The system of any of the previous clauses, wherein the alignment sensor and/or the overlay detection sensor is configured for a semiconductor wafer, and is used in a semiconductor manufacturing process.
20. A metrology system, comprising: a first optical element formed by a rotatable disk comprising at least one multi-aperture pattern, the first optical element positioned in a pupil plane of the system, the first optical element configured to receive radiation from a radiation source, and transmit portions of the radiation through transmissive portions of the at least one multi-aperture pattern and a relay lens pair toward a diffraction grating target; and a second optical element comprising a quad beam splitter with transmissive portions and reflective portions, the transmissive portions of the quad beam splitter configured to transmit a first portion of radiation received from the first optical element along a first optical path, and a second portion of the radiation along a second optical path, toward the diffraction grating target, and focus corresponding spots of radiation on the diffraction grating target, the reflective portions of the quad beam splitter configured to reflect diffracted radiation from the diffraction grating target along a third optical path toward a detector.
21. A metrology method, comprising: receiving radiation from a radiation source along a first optical path, and transmit portions of the radiation through transmissive portions of at least one multi-aperture pattern toward a diffraction grating target, the at least one multi-aperture pattern formed in an optical element, the at least one multi-aperture pattern comprising the transmissive portions and reflective portions, the optical element positioned in a pupil plane of a metrology system; and reflecting, with the reflective portions of the at least one multi-aperture pattern, diffracted radiation from the diffraction grating target along a second optical path toward a detector.
22. The method of any of the previous clauses, wherein about 50% of the radiation is transmitted through two transmissive quadrants of the at least one multi-aperture pattern, the two transmissive quadrants forming the transmissive portions of the at least one multi-aperture pattern.
23. The method of any of the previous clauses, wherein plus and minus first diffraction order diffracted radiation from the diffraction grating target is reflected by two reflective quadrants of the at least on multi-aperture pattern, the two reflective quadrants located on a back or non-radiation source facing side of the optical element, the two reflective quadrants forming the reflective portions of the at least one multi-aperture pattern.
24. The method of any of the previous clauses, wherein the optical element is an illumination mode selector.
25. The method of any of the previous clauses, wherein the illumination mode selector is movable to facilitate selection of the at least one multi-aperture pattern from among other different possible multi-aperture patterns.
26. The method of any of the previous clauses, wherein the illumination mode selector is a rotatable wheel with the at least one multi-aperture pattern and the other different possible multi-aperture patterns formed therein.
27. The method of any of the previous clauses, wherein the at least one multi-aperture pattern comprises four quadrants, with first and third opposing quadrants comprising two opposing apertures forming the transmissive portions, and second and fourth opposing quadrants comprising the reflective portions of the at least one multi-aperture pattern.
28. The method of any of the previous clauses, wherein the two opposing apertures are configured to split the radiation into a first sub-beam and a second sub-beam, direct the first sub-beam through a first optical branch of the system to form a first spot, and direct the second sub-beam through a second optical branch of the system to form a second spot.
29. The method of any of the previous clauses, wherein the reflective portions are configured to reflect diffracted plus and minus first order radiation through a detector branch of the system along the second optical path to the detector; wherein the detector is configured to receive the diffracted first order radiation and generate a detection signal.
30. The method of any of the previous clauses, further comprising transmitting, with an alignment branch beam splitter, transmitted radiation from the transmissive portions of the at least one multi-aperture pattern, wherein the alignment branch beam splitter is not in a common path with the detector branch.
31. The method of any of the previous clauses, wherein the alignment branch beam splitter is a transmissive optic cube.
32. The method of any of the previous clauses, wherein the alignment branch beam splitter is positioned between the optical element and the diffraction grating target, and wherein the optical element is not coupled to an alignment branch of the metrology system.
33. The method of any of the previous clauses, wherein the at least one multi-aperture pattern comprises two opposing apertures that form the transmissive portions, each opposing aperture comprising an orifice shaped as a sector of a circle.
34. The method of any of the previous clauses, further comprising replacing a quad non polarizing beam splitter in the metrology system with the optical element.
35. The method of any of the previous clauses, wherein the reflective portions are formed by coating a reflective coating on select portions of an optical element body.
36. The method of any of the previous clauses, further comprising generating, with the radiation source, the radiation along the first optical path.
37. The method of any of the previous clauses, further comprising receiving, with the detector, diffracted and reflected first order radiation from first and second illumination spots on diffraction grating targets and generating a detection signal with the detector.
38. The method of any of the previous clauses, wherein the optical element forms a portion of an alignment sensor and/or an overlay detection sensor.
39. The method of any of the previous clauses, wherein the alignment sensor and/or the overlay detection sensor is configured for a semiconductor wafer, and is used in a semiconductor manufacturing process.
40. A metrology method, comprising: receiving radiation from a radiation source with a first optical element formed by a rotatable disk comprising at least one multi-aperture pattern, the first optical element positioned in a pupil plane of the system, and transmitting portions of the radiation through transmissive portions of the at least one multi-aperture pattern and a relay lens pair toward a diffraction grating target; and transmitting, with a second optical element comprising a quad beam splitter with transmissive portions and reflective portions, a first portion of radiation received from the first optical element along a first optical path, and a second portion of the radiation along a second optical path, toward the diffraction grating target, and focus corresponding spots of radiation on the diffraction grating target, the reflective portions of the quad beam splitter configured to reflect diffracted radiation from the diffraction grating target along a third optical path toward a detector.
41. A system for generating spots of radiation configured to be directed at a diffraction grating target for an overlay detection sensor used in a semiconductor manufacturing process, the system configured to generate multiple spots of radiation, the system configured to eliminate a need for a quad non polarizing beam splitter and therefore a need for alignment image stitching, the system comprising: a radiation source; an illumination mode selector comprising at least one multi-aperture pattern having transmissive portions and reflective portions, the illumination mode selector positioned in a pupil plane of the system, the illumination mode selector configured to: receive radiation from the radiation source along a first optical path, and transmit portions of the radiation through the transmissive portions of the at least one multi-aperture pattern toward the diffraction grating target; and reflect, with the reflective portions of the at least one multi-aperture pattern, diffracted radiation from the diffraction grating target along a second optical path toward a detector; wherein about 50% of the radiation is transmitted through two transmissive quadrants of the at least one multi-aperture pattern, the two transmissive quadrants forming the transmissive portions of the at least one multi-aperture pattern; and wherein plus and minus first diffraction order diffracted radiation from the diffraction grating target is reflected by two reflective quadrants of the at least on multi-aperture pattern, the two reflective quadrants located on a back or non-radiation source facing side of the optical element, the two reflective quadrants forming the reflective portions of the at least one multi-aperture pattern; and the detection sensor, the detection sensor configured to receive diffracted and reflected plus and minus first order radiation from the diffraction grating target and generate an overlay detection signal based on the diffracted and reflected plus and minus first order radiation.
42. The system of any of the previous clauses, wherein the illumination mode selector is a rotatable wheel with the at least one multi-aperture pattern and other different possible multi-aperture patterns formed therein, such that the illumination mode selector is configured to facilitate selection of the at least one multi-aperture pattern from among the other different possible multi-aperture patterns.
43. The system of any of the previous clauses, wherein the at least one multi-aperture pattern comprises four quadrants, with first and third opposing quadrants comprising two opposing apertures forming the transmissive portions, each opposing aperture comprising an orifice shaped as a sector of a circle, and second and fourth opposing quadrants comprising the reflective portions.
44. The system of any of the previous clauses, wherein the two opposing apertures are configured to split the illumination into a first sub-beam and a second sub-beam, direct the first sub-beam through a first optical branch of the system to form a first spot, and direct the second sub-beam through a second optical branch of the system to form a second spot.
45. The system of any of the previous clauses, wherein the reflective portions are configured to reflect diffracted plus and minus first order radiation, through a detector branch of the system along the second optical path to the detection sensor; wherein the detection sensor is configured to receive the diffracted and reflected first order radiation and generate a detection signal.

The concepts disclosed herein may be associated with any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

While the concepts disclosed herein may be used for imaging on a substrate such as a silicon wafer, it shall be understood that the disclosed concepts may be used with any type of lithographic imaging systems, e.g., those used for imaging on substrates other than silicon wafers. In addition. the combination and sub-combinations of disclosed elements may comprise separate embodiments.

The descriptions above are intended to be illustrative, not limiting. Thus, it will be apparent to one skilled in the art that modifications may be made as described without departing from the scope of the claims set out below.

1. A metrology system, comprising:
an optical element comprising at least one multi-aperture pattern with transmissive and reflective portions, the optical element positioned in a pupil plane of the system, the optical element configured to:
receive radiation from a radiation source along a first optical path, and transmit portions of the radiation through the transmissive portions of the at least one multi-aperture pattern toward a diffraction grating target; and
reflect, with the reflective portions of the at least one multi-aperture pattern, diffracted radiation from the diffraction grating target along a second optical path toward a detector.

2. The system of claim 1, wherein about 50% of the radiation is transmitted through two transmissive quadrants of the at least one multi-aperture pattern, the two transmissive quadrants forming the transmissive portions of the at least one multi-aperture pattern.

3. The system of claim 1, wherein plus and minus first diffraction order diffracted radiation from the diffraction grating target is reflected by two reflective quadrants of the at least one multi-aperture pattern, the two reflective quadrants located on a back or non-radiation source facing side of the optical element, the two reflective quadrants forming the reflective portions of the at least one multi-aperture pattern.

4. The system of claim 1, wherein the optical element is an illumination mode selector.

5. The system of claim 4, wherein the illumination mode selector is movable to facilitate selection of the at least one multi-aperture pattern from among other different possible multi-aperture patterns.

6. The system of claim 5, wherein the illumination mode selector is a rotatable wheel with the at least one multi-aperture pattern and the other different possible multi-aperture patterns formed therein.

7. The system of 1, wherein the at least one multi-aperture pattern comprises four quadrants, with first and third opposing quadrants comprising two opposing apertures forming the transmissive portions, and second and fourth opposing quadrants comprising the reflective portions of the at least one multi-aperture pattern.

8. The system of claim 7, wherein the two opposing apertures are configured to split the radiation into a first sub-beam and a second sub-beam, direct the first sub-beam through a first optical branch of the system to form a first spot, and direct the second sub-beam through a second optical branch of the system to form a second spot.

9. The system of claim 8, wherein the reflective portions are configured to reflect diffracted plus and minus first order radiation through a detector branch of the system along the second optical path to the detector; wherein the detector is configured to receive the diffracted first order radiation and generate a detection signal.

10. The system of claim 9, further comprising an alignment branch beam splitter configured to transmit transmitted radiation from the transmissive portions of the at least one multi-aperture pattern, wherein the alignment branch beam splitter is not in a common path with the detector branch.

11. The system of claim 10, wherein the alignment branch beam splitter is a transmissive optic cube.

12. The system of claim 10, wherein the alignment branch beam splitter is positioned between the optical element and the diffraction grating target, and wherein the optical element is not coupled to an alignment branch of the metrology system.

13. The system of claim 1, wherein the at least one multi-aperture pattern comprises two opposing apertures that form the transmissive portions, each opposing aperture comprising an orifice shaped as a sector of a circle.

14. The system of claim 1, wherein the optical element is configured to replace a quad non polarizing beam splitter in the metrology system.

15. The system of claim 1, wherein the reflective portions are formed by coating a reflective coating on select portions of an optical element body.

16. The system of claim 1, further comprising the radiation source, the radiation source configured to generate the radiation along the first optical path.

17. The system of claim 1, further comprising the detector, the detector configured to receive diffracted and reflected first order radiation from first and second illumination spots on diffraction grating targets and generate a detection signal.

18. The system of claim 1, wherein the optical element forms a portion of an alignment sensor and/or an overlay detection sensor.

19. The system of claim 18, wherein the alignment sensor and/or the overlay detection sensor is configured for a semiconductor wafer, and is used in a semiconductor manufacturing process.

20. A metrology system, comprising:
a first optical element formed by a rotatable disk comprising at least one multi-aperture pattern, the first optical element positioned in a pupil plane of the system, the first optical element configured to receive radiation from a radiation source, and transmit portions of the radiation through transmissive portions of the at least one multi-aperture pattern and a relay lens pair toward a diffraction grating target; and
a second optical element comprising a quad beam splitter with transmissive portions and reflective portions, the transmissive portions of the quad beam splitter configured to transmit a first portion of radiation received from the first optical element along a first optical path, and a second portion of the radiation along a second optical path, toward the diffraction grating target, and focus corresponding spots of radiation on the diffraction grating target, the reflective portions of the quad beam splitter configured to reflect diffracted radiation from the diffraction grating target along a third optical path toward a detector.
